(19) United States
(12) Patent Application Publication
(10) Pub. No.: US 2026/0189209 A1
(43) Pub. Date: Jul. 2, 2026

(54) OVERTONE RESONATORS FOR TIMING APPLICATIONS

(71) Applicant: SKYWORKS SOLUTIONS, INC., Irvine, CA (US)

(72) Inventors: Scott J. Smith, Hollis, NH (US); Guillaume Alexandre Blin, Carlisle, MA (US); Ahmed E. Hassanien, Savoy, IL (US); Alexandre Augusto Shirakawa, Cardiff by the Sea, CA (US)

(21) Appl. No.: 19/213,446

(22) Filed: May 20, 2025

Related U.S. Application Data
(60) Provisional application No. 63/650,497, filed on May 22, 2024.

(51) Int. Cl. H03H 9/02; H03H 9/17

(52) U.S. Cl. CPC H03H 9/0207; H03H 9/175

(57) ABSTRACT

EnzyFloss is an innovative interdental cleaning device that integrates diagnostic and oral health functionality into a standard dental flosser. The floss string is coated with a unique combination of enzymes: amylase, protease, and lipase, long with a pH-sensitive dye and candelilla wax, enabling the detection of early oral health issues such as plaque accumulation, bacterial activity, or imbalanced oral pH. The biodegradable handle is ergonomically designed and inscribed with inspirational scripture for user encouragement. This multifunctional design advances the art by transforming flossing into a proactive oral health screening tool, unlike traditional flossers which only provide mechanical cleaning.

### FIELD

This invention relates to the field of oral hygiene and diagnostic dental care, and more specifically to biochemical dental floss products that incorporate enzyme-based detection systems for identifying early signs of oral health imbalances such as bacterial overgrowth or poor pH conditions.

### BACKGROUND

The present invention relates to the field of oral hygiene and preventative dental care, more particularly to dental floss embedded with diagnostic and therapeutic enzymes for detecting and addressing imbalances in the oral microbiome.

Traditional dental floss products are limited to the mechanical removal of plaque and food debris from interproximal spaces. However, they do not provide any indication of underlying biochemical conditions that may contribute to oral health issues such as gingivitis, cavities, or pH imbalance. There is a growing need for oral hygiene products that do more than just clean, particularly those that can help detect early signs of oral disease, monitor microbial activity, and support individualized preventive care.

The present invention addresses these unmet needs by providing a dental floss that incorporates a blend of enzymes (such as amylase, protease, and lipase) along with a color-change pH indicator, offering a visual cue to the user about potential microbial imbalances or poor hygiene conditions in the mouth. This innovation bridges the gap between traditional flossing and oral diagnostics, providing users with real-time feedback and potentially reducing the onset of dental diseases through early detection.

### SUMMARY

The present invention relates to a novel oral hygiene device known as EnzyFloss, which combines traditional interdental cleaning with enzymatic and diagnostic functionality in a sustainable and user-friendly form. EnzyFloss comprises a biodegradable floss stick and floss string, both engineered to provide enhanced oral care through mechanical, chemical, and sensory features.

The floss string is coated with a proprietary blend of enzymes-including amylase, protease, and lipase, that assist in breaking down food particles, biofilm, and plaque between the teeth. In addition, a pH-sensitive color indicator dye is embedded in the floss to visually alert the user to acidic oral conditions, which may correlate with increased bacterial activity or potential dental issues. The floss string is further enhanced with a natural candelilla wax coating, improving gliding comfort and ensuring stability of the enzyme formulation during use.

The floss holder is ergonomically shaped for comfortable handling, featuring a curved grip and a biodegradable body made from polylactic acid (PLA) or other plant-based polymers. The structural design includes front, top, and side contours that support effective flossing while minimizing waste. The design also provides dimensional specifications suitable for both adult and pediatric use, typically measuring approximately 85 mm in length, 7 mm in handle width, 15 mm in floss arc width and 2 mm thickness.

The handle will include engraved or molded inspirational text or Bible scriptures, providing motivational or spiritual encouragement during daily oral care routines. These inscriptions do not interfere with the functional aspects of the device but add emotional or psychological benefit to the user experience.

Together, these features define a dental flossing tool that not only improves the effectiveness and comfort of cleaning but also provides real-time biochemical feedback, supports eco-conscious living, and promotes positive behavioral reinforcement through integrated messaging.

### BRIEF DESCRIPTION OF THE DRAWING

The drawing of EnzyFloss illustrates the structural design and functional components of the dental flosser. They include front, side, top, and isometric views with labeled dimensions and material indicators, showcasing the enzyme-coated floss string, ergonomic biodegradable handle, and integrated wax and pH dye coatings and also a inspirational quote. These drawings provide a clear visual reference for the invention's form and intended use.

FIG. 1 is a front view of the EnzyFloss stick, according to the first embodiment.

FIG. 2 is a side view of the EnzyFloss stick, according to the second embodiment.

FIG. 3 is a top view of the EnzyFloss stick, according to the third embodiment.

FIG. 4 is an isometric view of EnzyFloss stick, according to the fourth embodiment.

### DETAILED DESCRIPTION

EnzyFloss is a novel dental hygiene tool designed to not only remove debris and plaque from interdental spaces but also to indicate the presence of specific biomolecules associated with oral health conditions. The invention combines traditional dental floss functionality with enzyme-based biochemical detection, embedded within the floss string itself, offering users a diagnostic advantage during routine oral care.

The EnzyFloss stick consists of a biodegradable polylactic acid (PLA) handle featuring an ergonomic curved grip for ease of use, and a floss head containing a U-shaped segment that holds the floss string. The floss string is composed of biodegradable polymer fiber such as bamboo silk or nylon-4. This string is coated with a blend of biological reagents including amylase, protease, lipase enzymes, a pH-sensitive dye, and candelilla wax for smooth gliding and preservation of reagents.

An inspirational Bible scripture is inscribed along the handle for motivational purposes. This feature is visible in all views, typically etched into the PLA material using laser engraving or molded during production.

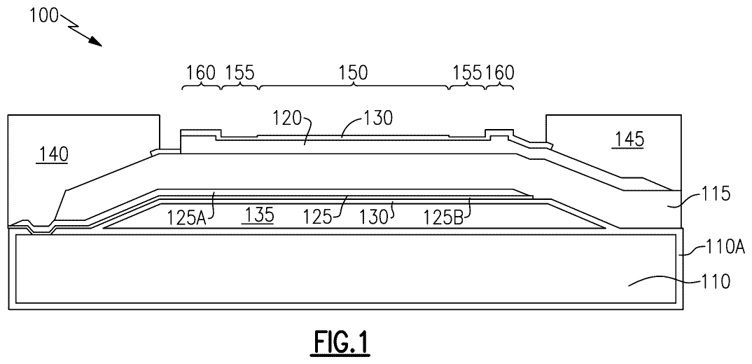

In this embodiment FIG. 1 (Front View) depicts the floss stick as seen from the front, illustrating the ergonomic handle, U-shaped floss head, and floss string. The floss string has arrows pointing to the coating components: amylase, protease, lipase enzymes, pH indicator dye, and candelilla wax. The biodegradable handle material and the integrated inspirational inscriptions are indicated. with dimension lines indicating total length (˜85 mm), handle width (˜7 mm), floss arc width (˜15 mm), and thickness (˜2 mm).

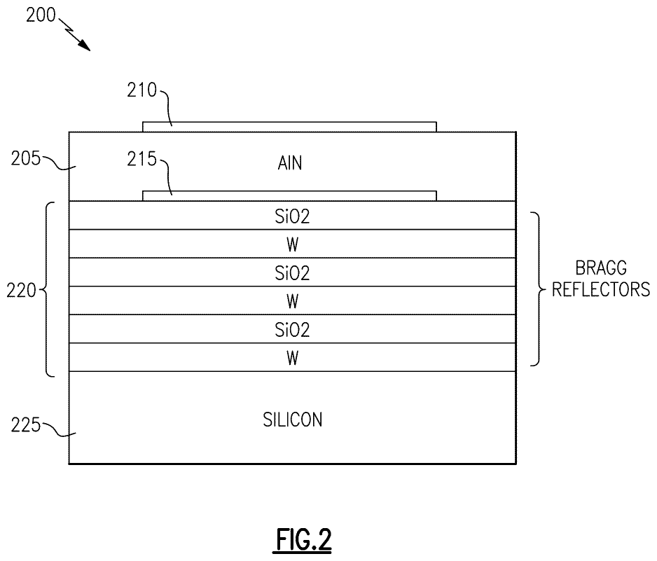

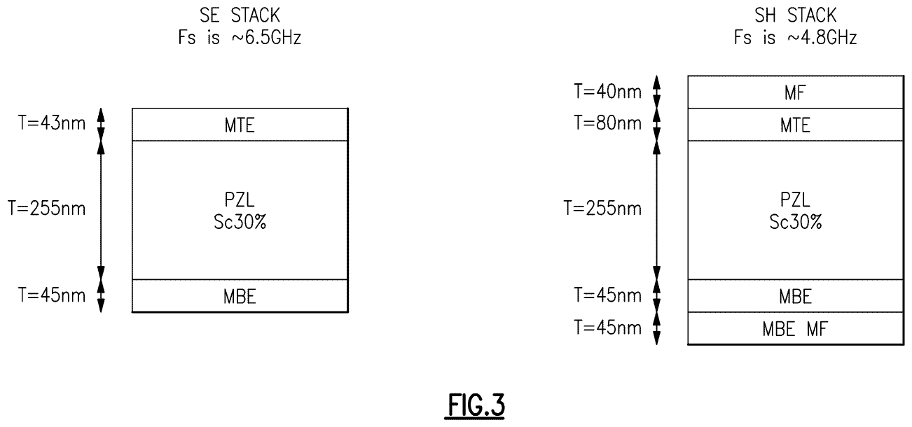

In this embodiment FIG. 2 (Side View) presents the side silhouette of Enzyfloss stick, showing the curved ergonomic profile of the handle for comfort and the approximate thickness of the device (˜2 mm). The straight alignment of the floss string is depicted at the top.

In this embodiment FIG. 3 (Top View) shows the floss pick from above, depicting the alignment of the floss arc and string, and its relative position to the handle. It illustrates the width of the floss arc (˜15 mm) and the top contour of the handle.

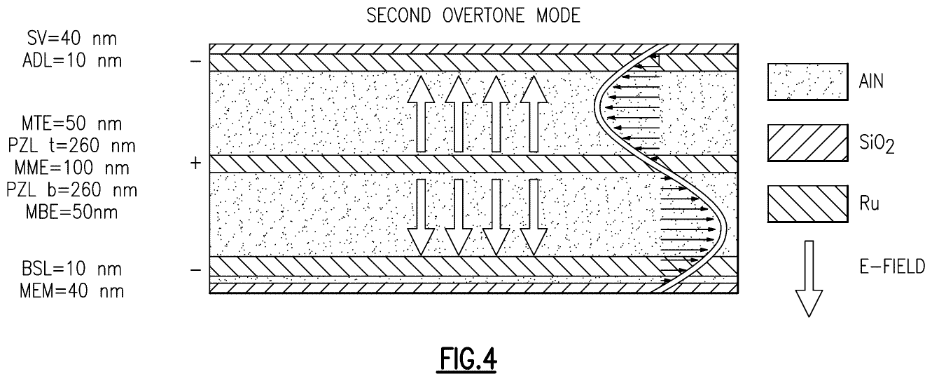

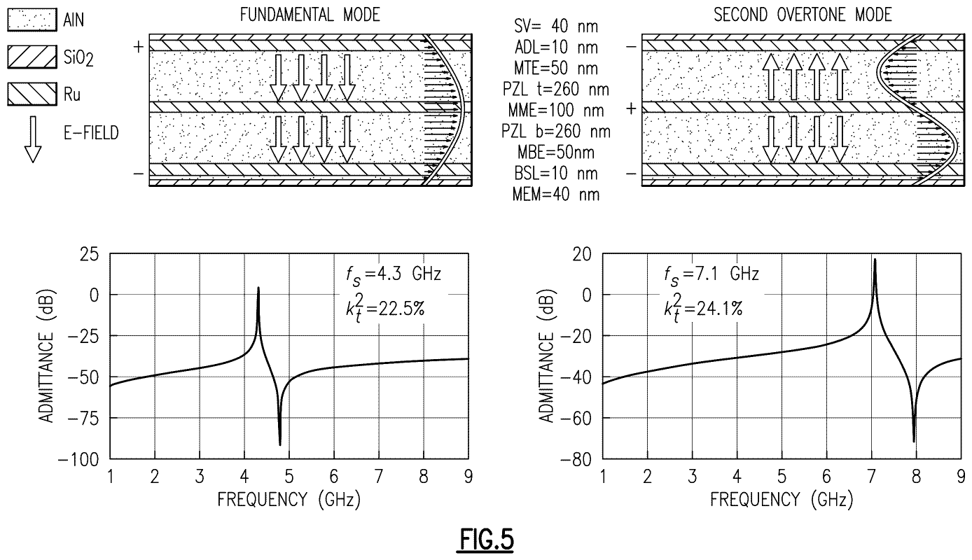

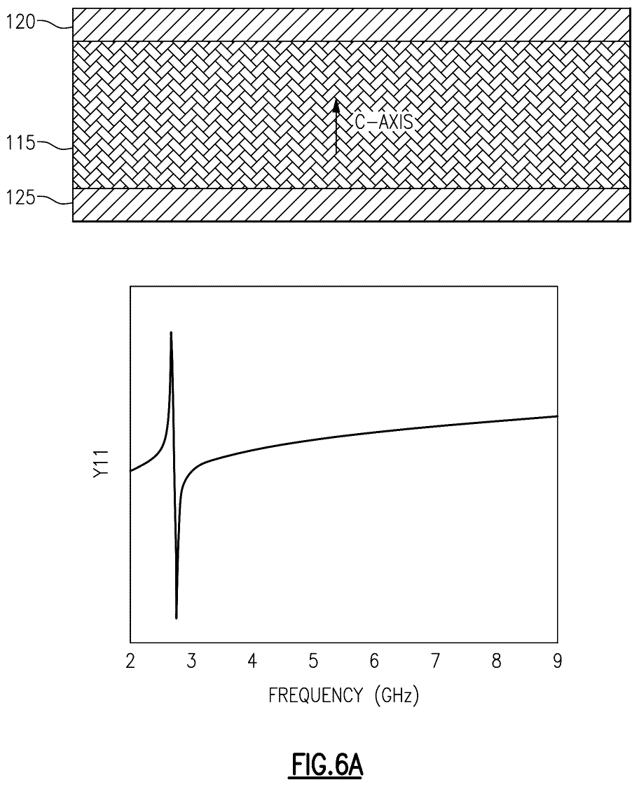

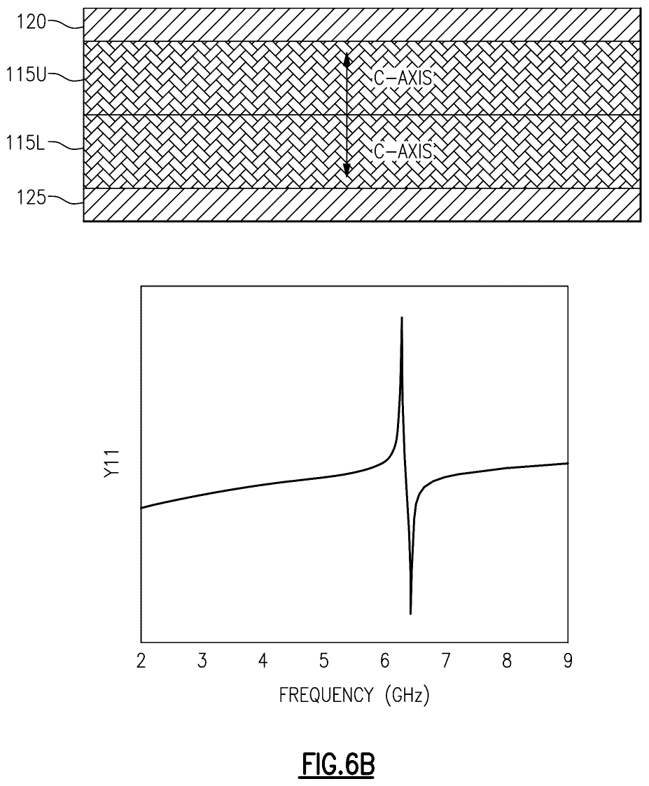

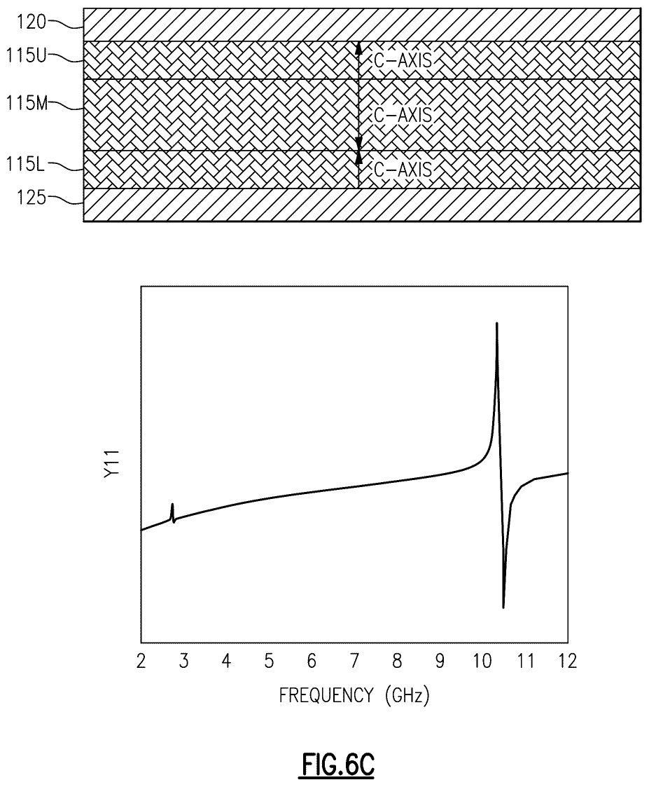

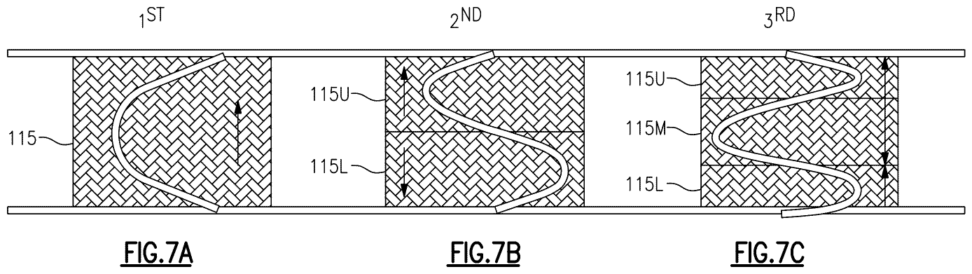

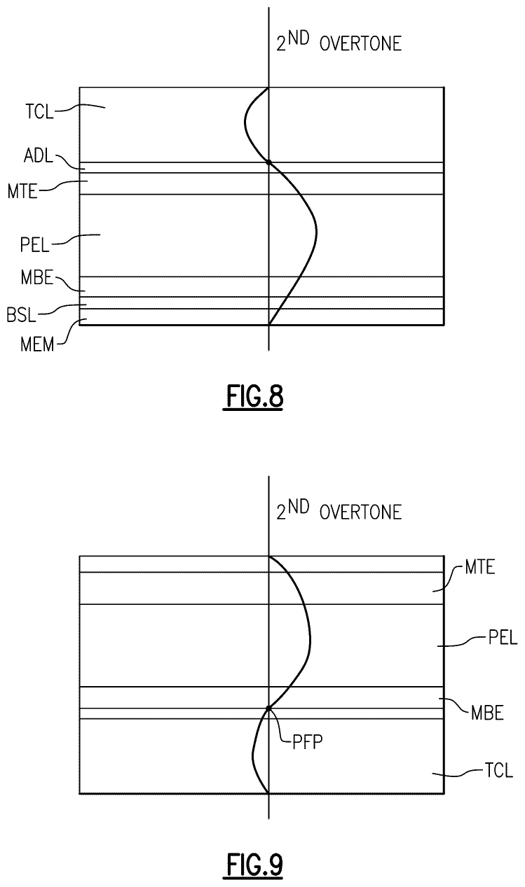

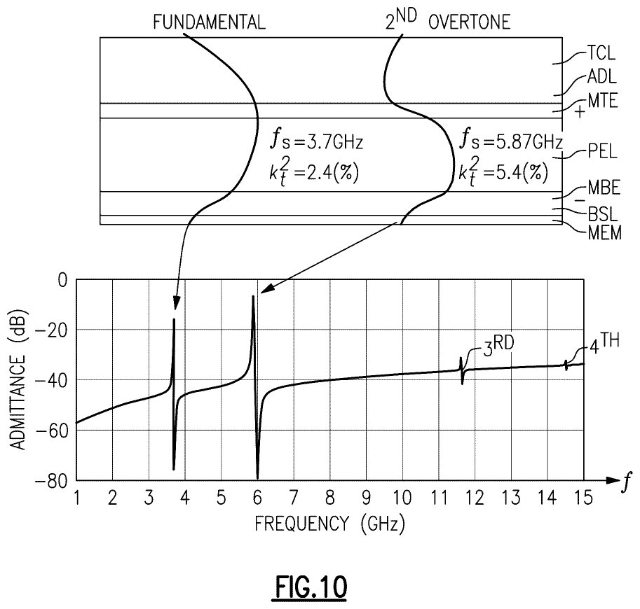

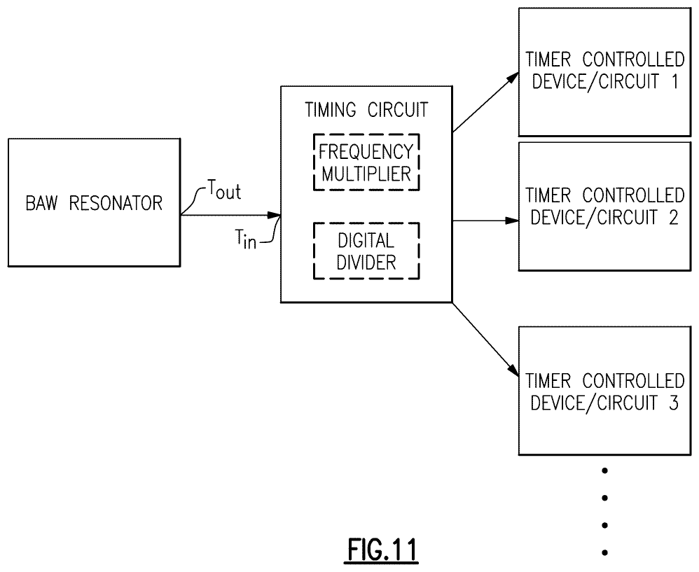

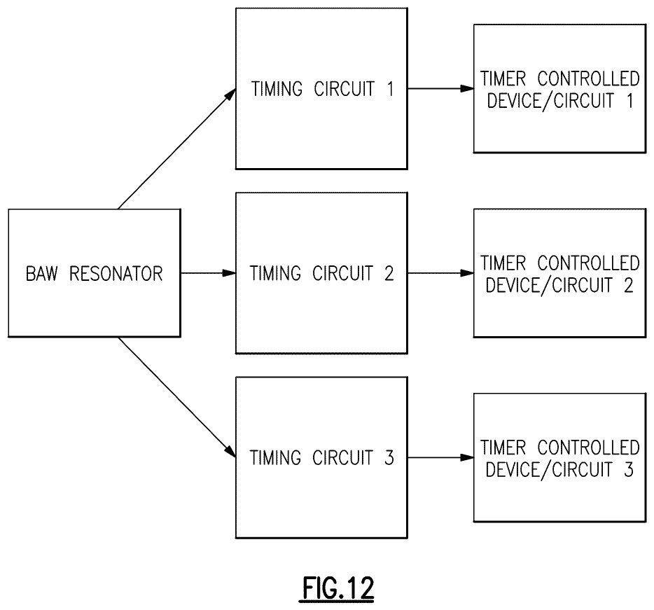

In this embodiment FIG. 4 (Isometric View) presents a three-dimensional isometric view of the EnzyFloss dental flosser, designed to provide a clear understanding of the product's overall shape, structure, and integrated features from an angled perspective.

This view combines visible aspects of the front, side, and top planes, offering a holistic perspective that highlights the ergonomic and functional design of the device. The handle and floss head appear in full form, demonstrating curvature, depth, and dimension.
The handle is shown to have an elongated, slightly curved profile that follows ergonomic principles for comfortable finger placement and firm grip during flossing. The width of the handle is approximately 7 mm, and the overall length of the device is 85 mm, both of which are visually proportioned in this figure.
The U-shaped floss head is clearly depicted at the top end of the device. The floss arc spans 15 mm, revealing how the floss string is suspended tightly between two parallel prongs. This string represents the active dental floss coated with amylase, protease, lipase enzymes, a pH-sensitive dye, and candelilla wax. These features are typically called out by labeled arrows in the figure.
The thickness of the device, approximately 2 mm, is evident from the depth and shadowing in the isometric view, giving viewers a sense of how slim and lightweight the flosser is.
Additional labeling in the isometric view may point to the biodegradable material used for the handle PLA (polylactic acid) and the plant-based polymer fiber for the floss string (such as bamboo-silk or nylon-4), which aligns with EnzyFloss's commitment to sustainability.
A subtle curvature and textured ergonomic grip zone may be visible along the handle's surface to improve user handling, especially during wet or slippery use. This figure serves to unify all perspectives into a cohesive representation, illustrating how each component relates to others in a spatial context and supporting a visual interpretation of the invention's form and intended use.

The coated floss string operates by interacting with saliva and debris caught between teeth. The enzymes react with biomolecules: amylase targets carbohydrates, protease targets proteins, and lipase targets fats. When these interactions occur, the pH dye changes color, providing a visual cue to the user. This indicator is embedded within the floss coating and appears as a strip along the floss string.

To manufacture Enzyfloss:
1. The handle is injection-molded from biodegradable PLA, shaped to include an ergonomic curve. integrated inspirational inscriptions are indicated.
2. The floss string is fabricated from biodegradable polymer strands and coated using a dip-coating process with a mixture of amylase, protease, lipase, pH dye, and candelilla wax.
3. The coated string is tension-mounted into the U-shaped floss head segment.

This invention significantly improves conventional floss by providing biochemical feedback. It is distinct from any existing floss or floss picks by incorporating diagnostic reagents into the floss string. The color-change feature introduces a new utility-oral biomarker detection, into a daily hygiene tool, bridging health awareness and preventive care.

Each feature shown in the figures is referenced herein, with:
(101) Floss String
(102) PLA Handle
(103) Ergonomic Curve
(104) Enzyme Indicator Zone (Amylase, Protease, Lipase, pH Dye)
(105) Inspirational Text
(106) U-Shaped Arc
(107) Floss Pick End

This invention can be replicated by a person of ordinary skill in polymer processing and biochemical engineering using standard industrial equipment, without requiring extensive experimentation.

The best mode currently contemplated by the inventor includes embedding the enzymes and dye in a pH-stable medium within the wax and applying the coating through precision micro-coating processes to ensure uniform enzyme distribution.

### Components

1. Floss Base: Polylactic Acid (PLA), Corn Starch, or Bamboo fiber (vegan and biodegradable)
2. Enzyme Coating: Amylase, Protease, Lipase (plant-derived, food-grade)
3. pH-Sensitive Dye: Food-safe indicator dye, responsive to enzymatic reaction byproducts
4. Candelilla wax layer for smoother use and protection of enzyme layer

### Use and Indication Mechanism

As the user flosses, the presence of food debris activates the enzymes. When debris is no longer detected, the dye stabilizes, causing a visible color change on the floss string, indicating that the area is clean. This provides real-time feedback and improves dental hygiene efficacy.

1. A dental floss device comprising a handle made from a biodegradable material, a U-shaped floss head extending from one end of the handle, and a floss string tensioned across the arms of the U-shaped floss head.

2. The dental floss device of claim 1, wherein the floss string is coated with a composition comprising at least one enzyme selected from the group consisting of amylase, protease, and lipase, a pH-sensitive dye, and candelilla wax.

3. The dental floss device of claim 1, wherein the handle includes an ergonomic grip with a contoured curvature to facilitate comfortable manual use.

4. The dental floss device of claim 1, wherein the handle is composed of polylactic acid (PLA), a biodegradable corn-starch-based polymer.

5. The dental floss device of claim 1, wherein the floss arc spans approximately 15 millimeters.

6. The dental floss device of claim 1, wherein the total length of the device is approximately 85 millimeters and the width of the handle is approximately 7 millimeters.

7. The dental floss device of claim 1, wherein the handle includes one or more finger indentations to improve grip stability during use.

8. The dental floss device of claim 1, wherein the handle includes an engraved inspirational message or scripture along its surface.

9. A coated dental floss string comprising a biodegradable or plant-based polymeric fiber and a surface coating that includes amylase, protease, and lipase enzymes, a pH-sensitive dye, and a natural wax selected from the group consisting of candelilla wax and carnauba wax.

10. The coated dental floss string of claim 9, wherein the pH-sensitive dye is configured to produce a visible color change in response to exposure to an oral environment with a pH below 5.5.

11. The coated dental floss string of claim 9, wherein the enzymes in the coating are microencapsulated to preserve stability prior to use.

12. The coated dental floss string of claim 9, wherein the polymeric fiber is selected from bamboo silk or biodegradable nylon.
